(19) United States
(12) Patent Application Publication
(10) Pub. No.: US 2006/0026474 A1
(43) Pub. Date: Feb. 2, 2006

(54) System and program product for displaying error handling information

(75) Inventor: Masato Honda, Nisshin-shi (JP)

Correspondence Address: BANNER & WITCOFF, LTD.;Counsel for Brother Industries, 1001 G STREET, N.W., 11TH FLOOR, WASHINGTON, DC, 20001-4597, US

(73) Assignee: BROTHER KOGYO KABUSHIKI KAISHA, Nagoya-shi (JP)

(21) Appl. No.: 11/187,907

(22) Filed: Jul. 25, 2005

(30) Foreign Application Priority Data
Jul. 27, 2004 (JP) 2004-219120

(51) Int. Cl. G01R 31/28

(52) U.S. Cl. 714/728

(57) ABSTRACT

When an emission pattern of LEDs of an operation panel of a printer is merely pseudo-displayed on display portions of a local computer and a server computer, a piece of error handling information corresponding to a pseudo pattern of the emission pattern can be acquired. Accordingly, a user can easily handle a generated error without any knowledge about the factor of the error and without any instruction manual.

### BACKGROUND

1. Field

A system for displaying pieces of error handling information on a screen of a display device, the pieces of error handling information corresponding to a plurality of errors of apparatus having a display portion for displaying a plurality of display patterns corresponding to the plurality of errors respectively, and a program product for displaying error handling information.

2. Related Art

In an apparatus such as a printer, various errors such as medium jam or necessity of replacement of consumables may occur so that an operation cannot be executed normally. Japanese Patent No. 3,308,852 discloses a configuration in which a plurality of LEDs provided on an operation panel of the image forming apparatus are operated to emit light with emission patterns corresponding to the aforementioned errors respectively so as to indicate which error has occurred.

On the other hand, JP-A-2003-058351 discloses a configuration in which an error signal corresponding to an error is transmitted to a communication terminal connected to the image forming apparatus when the error occurs, and estimated causes of the error are displayed on a display screen of the communication terminal.

In the configuration disclosed in the Japanese Patent No. 3,308,852, a maintenance work may be troublesome because a user has to grasp correspondence between the emission patterns of the LEDs and the contents of the errors. On the other hand, in the configuration disclosed in JP-A-2003-058351, for example, an error in communication between the image forming apparatus and the communication terminal may prevent the error signal from being transmitted from the image forming apparatus to the communication terminal. In this case, there is a problem that it is impossible to know which error has occurred.

### SUMMARY

A system and a program product display error handling information capable of handling various errors easily.

A system includes: an apparatus having a display portion that displays a plurality of display patterns corresponding to a plurality of errors respectively; and a terminal apparatus that has a display device that displays images of pieces of error handling information corresponding to the errors respectively. The terminal apparatus includes: a pseudo pattern display unit that displays pseudo patterns corresponding to the display patterns respectively; a designation unit that designates a specific pseudo pattern from among the pseudo patterns in accordance with an input signal from an input unit connected to the terminal apparatus; and an error handling information output unit that reads one piece of error handling information corresponding to the specific pseudo pattern designated by the designation unit from among a plurality of pieces of error handling information, and outputs the read error handling information to be displayed.

On the other hand, a system includes: an image forming apparatus that forms an image on a recording medium; and a terminal apparatus that has a display device that displays images of pieces of error handling information corresponding to various image formation failure patterns in the image forming apparatus respectively. The terminal apparatus includes: a pseudo pattern display unit that displays pseudo patterns corresponding to the various image formation failure patterns respectively; a designation unit that designates a specific pseudo pattern from among the pseudo patterns in accordance with an input signal from an input unit connected to the terminal apparatus and an error handling information output unit that reads one piece of error handling information corresponding to the specific pseudo pattern designated by the designation unit from among a plurality of pieces of error handling information stored in a storage unit, and outputs the read error handling information to be displayed.

On the other hand, a terminal apparatus includes: a display device that displays images of pieces of error handling information corresponding to a plurality of errors in an apparatus having a display portion that displays a plurality of display patterns corresponding to the plurality of the errors respectively; a pseudo pattern display unit that displays pseudo patterns corresponding to the display patterns respectively; a designation unit that designates a specific pseudo pattern from among the pseudo patterns in accordance with an input signal from an input unit connected to the terminal apparatus; and an error handling information output unit that reads one piece of error handling information corresponding to the specific pseudo pattern designated by the designation unit from among a plurality of pieces of error handling information, and outputs the read error handling information to be displayed.

On the other hand, a terminal apparatus includes: a display device that displays images of pieces of error handling information corresponding to various image formation failure patterns in the image forming apparatus respectively; a pseudo pattern display unit that displays pseudo patterns corresponding to the various image formation failure patterns respectively; a designation unit that designates a specific pseudo pattern from among the pseudo patterns in accordance with an input signal from an input unit connected to the terminal apparatus; and an error handling information output unit that reads one piece of error handling information corresponding to the specific pseudo pattern designated by the designation unit from among a plurality of pieces of error handling information stored in a storage unit, and outputs the read error handling information to be displayed.

On the other hand, a computer readable program product causes a computer to display pieces of error handling information on a screen of a display device connected to the computer, the pieces of error handling information corresponding to a plurality of errors of an image forming apparatus having a display portion for displaying a plurality of display patterns corresponding to the plurality of errors respectively. The program product causes the computer to execute procedures including: displaying pseudo patterns corresponding to the display patterns respectively; designating a specific pseudo pattern from among the pseudo patterns in accordance with an input signal input from an input unit connected to the computer; reading one piece of error handling information corresponding to the designated specific pseudo pattern from among a plurality of pieces of error handling information; and outputting the read error handling information to be displayed.

On the other hand, a computer readable program product causes a computer to display pieces of error handling information on a screen of a display device connected to the computer, the pieces of error handling information corresponding respectively to various image formation failure patterns in an image forming apparatus that forms an image on a recording medium. The program product causes the computer to execute procedures including: displaying pseudo patterns corresponding to the image formation failure patterns respectively; designating a specific pseudo pattern from among the pseudo patterns in accordance with an input signal input from an input unit connected to the computer; reading one piece of error handling information corresponding to the designated specific pseudo pattern from among a plurality of pieces of error handling information; and outputting the read error handling information to be displayed.

On the other hand, a system includes an apparatus that visually outputs a plurality of error information; and a terminal apparatus that visually outputs a plurality of pseudo error information corresponding to the error information, wherein the terminal apparatus allows a user to designate a specific pseudo error information from among the plurality of pseudo pattern information, and outputs an error handling information corresponding to the specific pseudo error information designated by the user.

### BRIEF DESCRIPTION OF THE DRAWINGS

In the accompanying drawings:

FIG. 1 is a view of an overall configuration of a network system according to a first embodiment;

FIG. 2 is a perspective view showing the external appearance of a printer;

FIG. 3 is a side sectional view showing the internal configuration of the printer;

FIG. 4 is an enlarged view showing a portion of an operation panel of the printer;

FIG. 5 is a table of correspondence between emission patterns of LEDs and error names;

FIG. 6 is a flowchart for indicating the contents of control by a CPU;

FIGS. 7A-7D are views showing display screens;

FIG. 8 is a table of correspondence between error names and error handling information;

FIGS. 9A and 9B are an enlarged view of a portion of an operation panel of a printer according to a second embodiment, and a view of a pseudo display screen of the operation panel;

FIG. 10 is a table of correspondence between printing failure patterns and pieces of error handling information according to a third embodiment; and

FIG. 11 is an example of a view showing a screen on which pseudo patterns are displayed by a list according to a modification.

### DETAILED DESCRIPTION OF THE PREFERRED EMBODIMENTS

An embodiment will be described below with reference to the drawings.

### First Embodiment

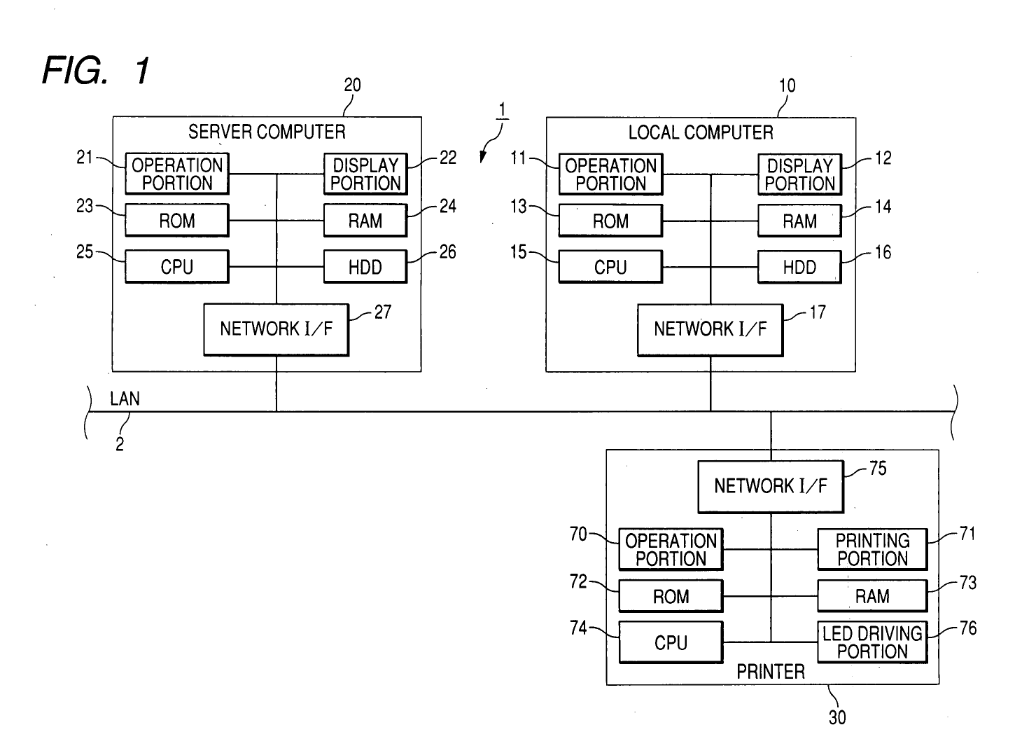

A first embodiment will be described with reference to FIGS. 1 to 8.

1. Configuration of the First Embodiment

FIG. 1 shows the configuration of a network system 1 corresponding to the “system” according to the invention. In the network system 1, for example, a plurality of local computers 10 (only one of which is shown in FIG. 1) corresponding to the “terminal apparatus” according to the invention, a sever computer 20 (corresponding to the “terminal apparatus” according to the invention), and a printer 30 corresponding to the “apparatus” according to the invention are connected to one another through an LAN 2 (Local Area Network) so that data communication can be made among the local computers 10, the server computer 20 and the printer 30. As will be described later, in the network system 1 according to this embodiment, pieces of error handling information respectively corresponding to errors which may occur in the printer 30 are displayed on a screen of a display portion 12 or 22 of each local computer 10 or the sever computer 20 so that the errors can be solved smoothly.

(1) Local Computers and Server Computer

Each of the local computers 10 and the server computer 20 includes an operation portion 11, 21 for accepting an input operation from an external devices (an input devices such as a keyboard and a mouse); a display portion 12, 22 (which serves as a “display device” according to the invention) for displaying a pseudo panel screen 80, error handling information 81, etc. which will be described later; a ROM 13, 23; a RAM 14, 24; a CPU 15, 25; a hard disk 16, 26; and a network interface 17, 27. Application software for creating information to be printed, a printer driver, an error handling information display program, etc. are stored in the hard disk 16, 26 (which serves as a “storage unit” according to the invention). The CPU 15, 25 reads the application software, the printer driver, etc. from the hard disk 16, 26 and activates them in accordance with an activation command from the operation portion 11, 21.

When a print request command is received from the operation portion 11, 21 due to a user's input operation, data to be printed generated by the application software is delivered to the printer driver. In the printer driver, the data is subjected to an expansion (conversion) process for converting the data into PDL data which can be subjected to a print process. Then, the data is transmitted through the network interface 17, 27.

The local computers 10 are used by users respectively. The server computer 20 stores and manages, for example, software, files, etc. shared by the users and supplies the software, these files, etc. to the local computers 10. It is a matter of course that the user's input operation may be performed through a graphical user interface, as well as through key input using a keyboard.

(2) Printer

(a) Structure

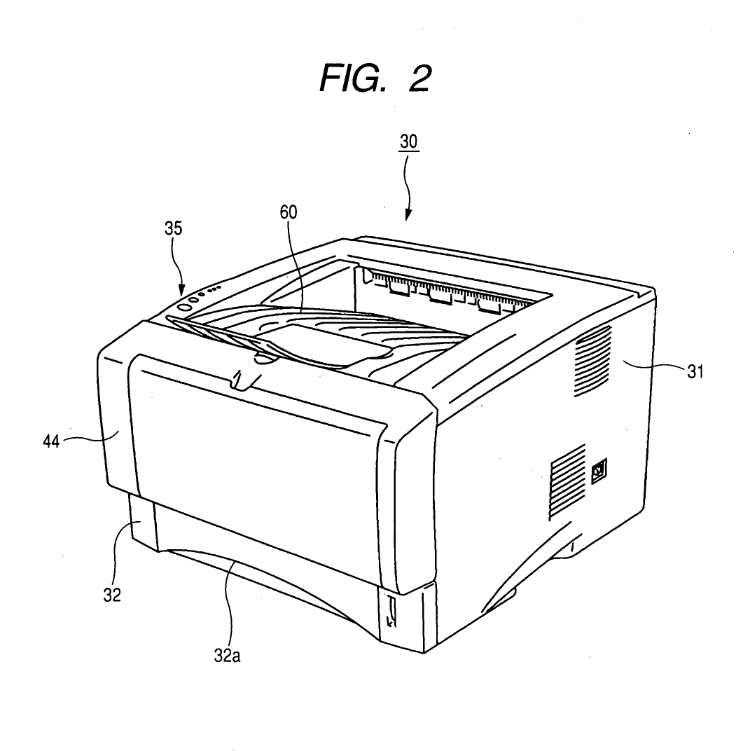

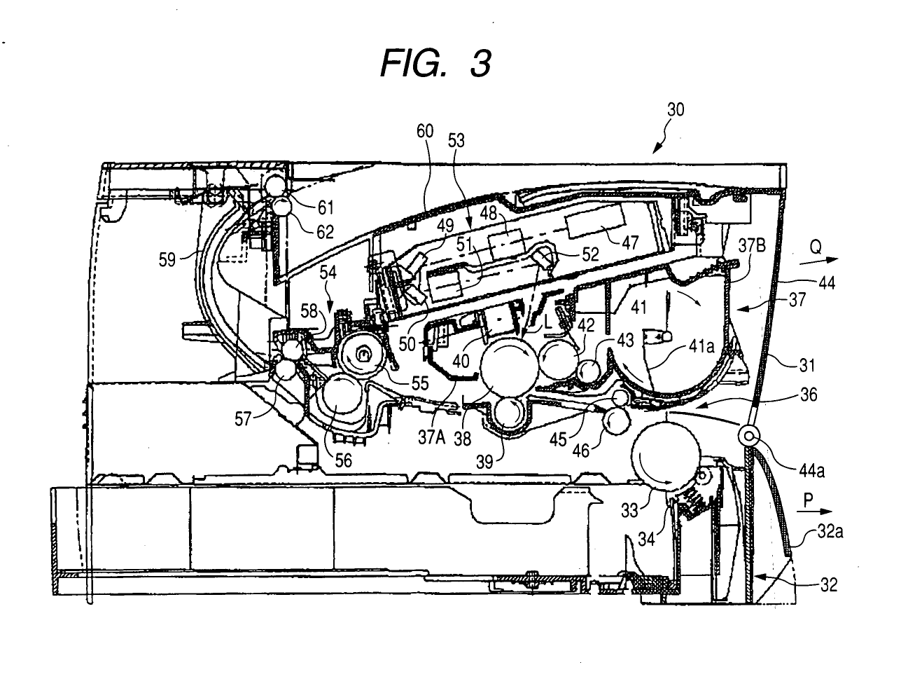

As shown in FIGS. 2 and 3, the printer 30 has a housing 31, and a paper feed cassette 32 storing a stack of sheets of paper and including a hand grip 32a is attached to the lower portion of the housing 31. The paper feed cassette 32 can be removably attached to the printer 30. When the paper feed cassette 32 is pulled out toward the front surface of the printer 30 (in the direction of an arrow P in FIG. 3), the paper feed cassette 32 can be removed from the printer 30. A paper pressure plate (not shown) urged upward by pressure springs (not shown) is provided in the paper feed cassette 32 so that an uppermost one of sheets of paper stacked on the paper pressure plate comes into contact with a paper feed roller 33. The paper feed roller 33 is provided in a body of the printer 30 so as to rotate in the direction designated by an arrow in FIG. 3. Thus, the sheets of paper are separated and fed one by one by the operation of a separation pad 34.

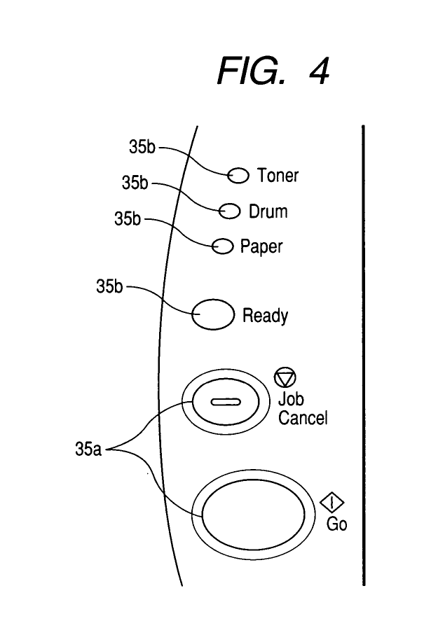

As shown in FIG. 2, an operation panel 35 (which serves as a “display portion” according to the invention) is provided in the upper surface of the printer 30. As shown in FIG. 4, only two operation buttons 35a and four LEDs 35b (which serves as a “light emitting lamps” according to the invention) are disposed in the operation panel 35, but no liquid crystal display portion or the like is provided. Incidentally, in this embodiment, upper two of the LEDs 35b emit yellow light, the next LED 35b emits red light and the lowest LED 35b emits green light. An insertion hole 36 (see FIG. 3) for manually inserting paper is provided in the front surface of the printer 30.

As shown in FIG. 3, a drum unit 37 is disposed above the paper feed cassette 32. Like the paper feed cassette 32, the drum unit 37 is made removable. For maintenance such as toner refilling, the drum unit 37 is pulled out in the direction of an arrow Q in FIG. 3. The drum unit 37 includes a photoconductor cartridge 37A and a development cartridge 37B. The photoconductor cartridge 37A includes a photoconductor drum 38 for transferring a toner image, a transfer roller 39 for transferring the toner image carried by the photoconductor drum 38 onto paper, and a scorotron type charger 40 for generating corona discharge and charging the surface of the photoconductor drum 38 with positive potential. The development cartridge 37B includes a developer chamber 41 for storing toner, a development roller 42 for feeding the toner to the photoconductor drum 38, and a feed roller 43 for feeding the toner to the development roller 42. An agitator 41a for agitating the toner is provided in the developer chamber 41.

Although the photoconductor cartridge 37A and the development cartridge 37B can be separated from each other, the both are pulled out integrally when the drum unit 37 is removed from the body of the printer 30. Assume that the side where the paper feed cassette is attached/detached is the front side. In this case, a front cover 44 whose lower end is rotatably attached to a rotary shaft 44a is provided in the front portion of the printer 30. The front cover 44 is designed to cover the front side of the printer 30. When the front cover 44 is rotated clockwise in FIG. 3 so as to open the front side of the printer 30, the drum unit 37 can be attached/detached. Incidentally, as shown in FIG. 3, a pinch roller 45 and a registration roller 46 are rotatably mounted between the drum unit 37 and the paper feed cassette 32.

A laser scanner unit 53 including a laser generator (not shown) for emitting a laser beam, a polygon mirror 47 (hexahedral mirror) to be driven to rotate, a lens 48, a reflecting mirror 49, a reflecting mirror 50, a lens 51, a reflecting mirror 52, etc. is mounted at the rear of the drum unit 37. As shown in FIG. 3, a laser beam L turned by the polygon mirror 47 is radiated onto the photoconductor drum 38 through the lens 48, the reflecting mirrors 49 and 50, the lens 51 and the reflecting mirror 52 so that an electrostatic latent image is formed on the surface of the photoconductor drum 38.

A fixing unit 54 for fixing toner on paper is provided at the rear of the drum unit 37. The fixing unit 54 includes a heating roller 55 for heating and melting toner transferred onto paper, a pressure roller 56 disposed oppositely to the heating roller 55 and for pressing the fed paper against the heating roller 55, and a pair of conveyance rollers 57 and 58.

In FIG. 3, a shooter 59 formed into a curved shape and for reversing the direction of paper in accordance with necessity is rotatably placed at the rear of the conveyance rollers 57 and 58. When the shooter 59 is rotated backward, the paper is ejected not to the paper ejection tray 60 but onto the shooter 59. Thus, paper conveyance or paper ejection can be performed linearly. Particularly when paper inserted manually is cardboard or the like, it is effective to use the shooter 59 in the aforementioned manner. A pair of paper ejection rollers 61 and 62 for supporting paper conveyed along the shooter 59 and ejecting the paper to the paper ejection tray 60 formed in the upper surface of the housing 31 are placed on an extension line of the shooter 59.

In the embodiment, the printer 30 assumed to be a laser printer. However, in the embodiment, any kind of printer, a facsimile machine, or a multifunction peripheral having a printer function and a scanner function may be used instead of the printer 30 as an “image forming apparatus” according to the invention.

(b) Software Configuration

A simplified software configuration of the printer 30 is shown in FIG. 1. The printer 30 includes an operation portion 70 for accepting a push-down operation on one of the operation buttons 35a of the operation panel 35, a printing portion 71 for controlling printing on a sheet of paper as a recording medium, a ROM 72, a RAM 73, a CPU 74, and a network interface 75. The CPU 74 performs a printer description language process (PDL process) on PDL data received from one of the local computers 10 or the server computer 20 through the network interface 75, and transmits the resulting PDL data to the printing portion 71. Based on the transmitted data, the printing portion 71 executes a printing operation so as to print information on paper in accordance with the aforementioned data to be printed.

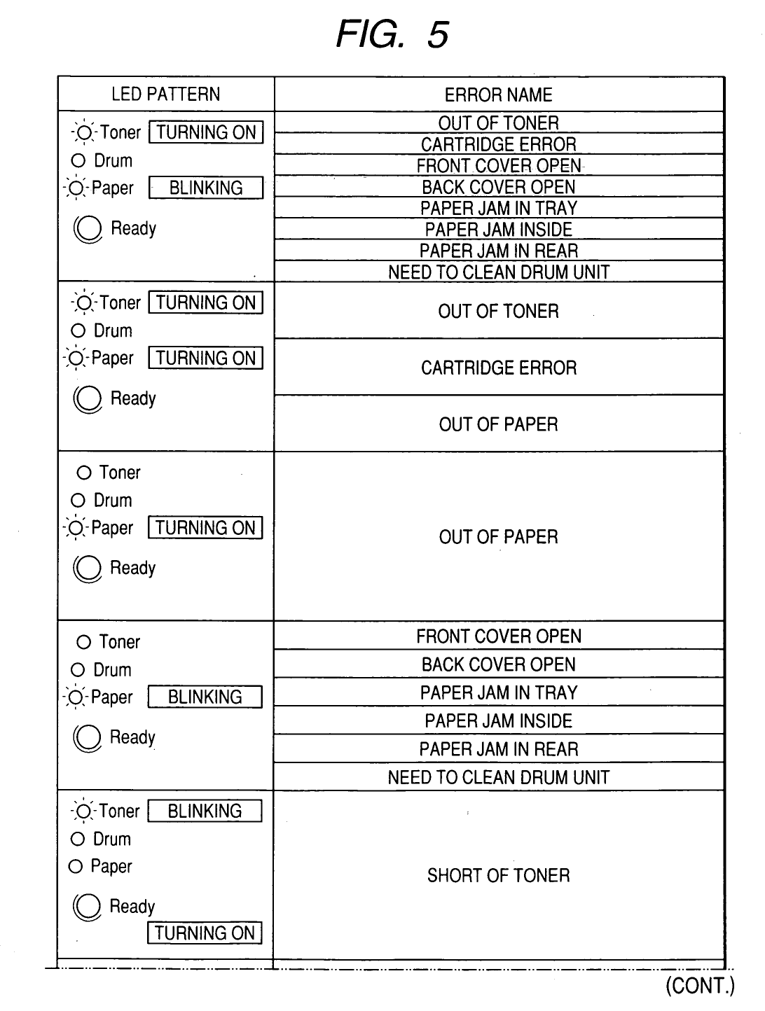

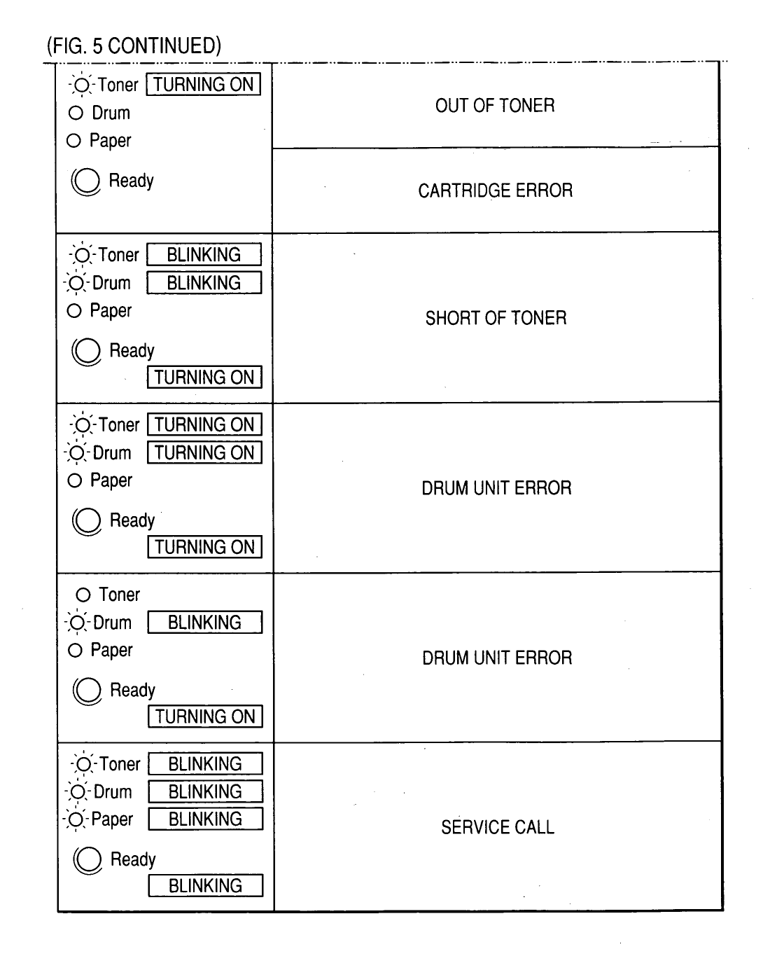

In the embodiment, the printer 30 further includes an LED driving portion 76 for operating the four LED 35b of the operation panel 35 to emit light. In this event, the CPU 74 receives an error signal of each error generated in the printer 30, and gives a control signal to the LED driving portion 76 in accordance with the error, so that the four LEDs 35b are operated to emit light with an emission pattern corresponding to the error. FIG. 5 shows correspondence between each error and each emission pattern.

2. Control by Error Handling Information Display Program

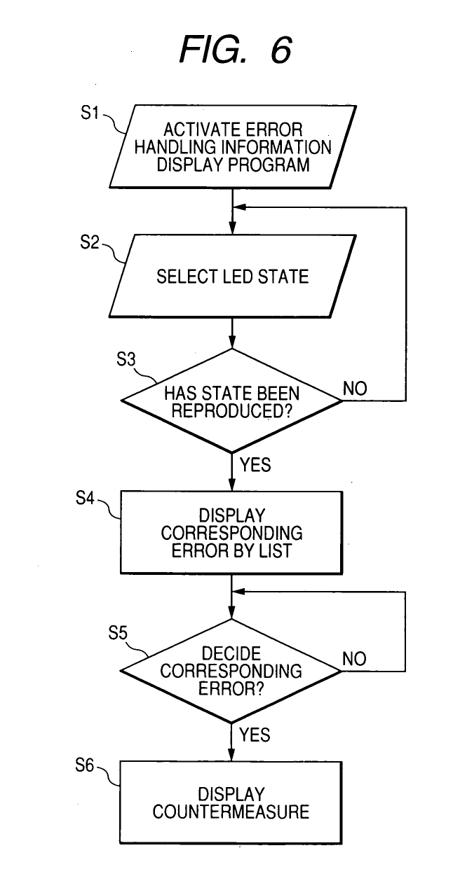

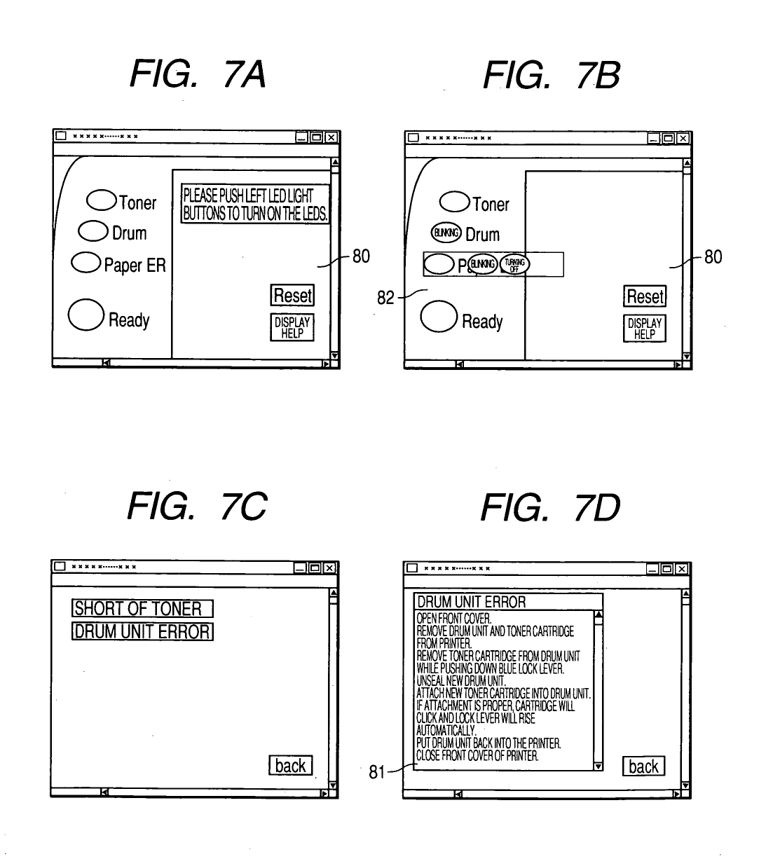

Assume that an given error occurs in the printer 30 and the LEDs 35b emit light with an emission pattern corresponding to the error. In this case, the user activates the error handling information display program, for example, in his/her own local computer 10 (S1 in FIG. 6). Then, the CPU 15 makes the display portion 12 display a pseudo panel screen 80 on the screen as shown in FIG. 7A. The pseudo panel screen 80 shows a pseudo display of the display panel 35 portion of the printer 30. Turning on, blinking or turning off can be selected on the pseudo panel screen 80 by clicking each pseudo LED 80a, as shown in FIG. 7B. Here, the user reproduces a pseudo pattern 82 (specific pseudo pattern), which is the same as the current emission pattern in the printer 30, on the pseudo panel screen 80 (S2) and performs a predetermined determination operation (“Y” in S3). On this occasion, the CPU 15 serves as the “pseudo pattern display unit” or the “designation unit” according to the invention.

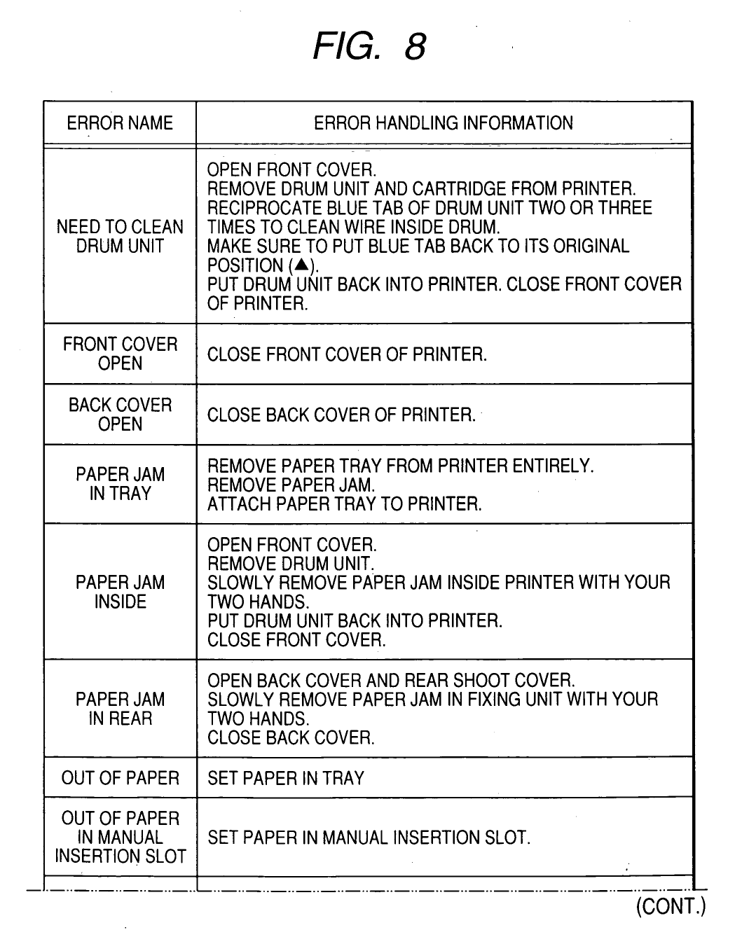

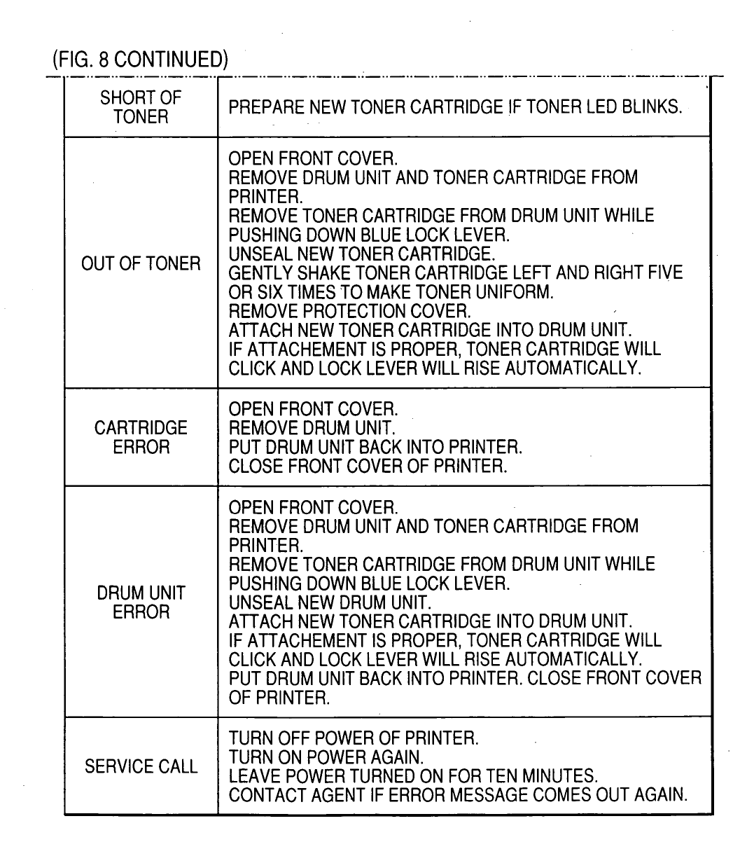

The CPU 15 displays, by a list, error names which have been associated with the specific pseudo pattern 82 by the aforementioned determination operation (S4) as shown in FIG. 7C. In this event, it is preferable to use a configuration in which the error names are displayed in order of descending rate of error incidence. When the user clicks one specific error name (“Y” in S5), the CPU 15 displays a piece of error handling information 81 associated with the specific error name on the screen (S6) as shown in FIG. 7D. On this occasion, the CPU 15 serves as the “error handling information output unit” according to the invention. FIG. 8 shows correspondence between each error name and each piece of error handling information. When there is a one-to-one correspondence between the pseudo patterns and the error names, the pseudo patterns and the pieces of error handling information associated with each other may be stored in advance so that a piece of error handling information associated with selected one of the pseudo patterns can be displayed on the screen directly.

Incidentally, the “display by a list” is not limited to the configuration in which all the pseudo patterns are displayed together on the screen but may be applied to the configuration in which a screen scroll function is used to scroll the screen so that the pseudo patterns are displayed successively on the screen with a predetermined number of pseudo patterns being displayed at a time.

3. Advantages of the Embodiment

(1) According to the embodiment, when the emission pattern of the LEDs 35b of the operation panel 35 of the printer 30 is merely pseudo-displayed on the display portions 12 and 22 of the local computer 10 and the server computer 20, a piece of error handling information 81 corresponding to the displayed pseudo pattern 82 can be acquired. Accordingly, the user can handle the generated error easily without any knowledge about the cause of the error and without any instruction manual.

(2) In addition, the pseudo display screen 80 corresponding to the operation panel 35 is displayed so that it is possible to reproduce the pseudo pattern 82 on the pseudo display screen 80. That is, the state near to the actual emission pattern of the LEDs 35b of the printer 30 are reproduced on the display screen. Accordingly, it becomes easy for the user to designate the specific pseudo pattern 82 visually.

Incidentally, the “patterns corresponding to emission patterns of the light emitting lamps” are not limited to those in which patterns the same as the emission patterns of the light emitting lamps (turning on, blinking, turning off, emission colors, and so on) are reproduced on the display screen. For example, the “patterns corresponding to emission patterns of the light emitting lamps” may be characters indicating turning on, blinking, turning off, emission colors, and the like.

### Second Embodiment

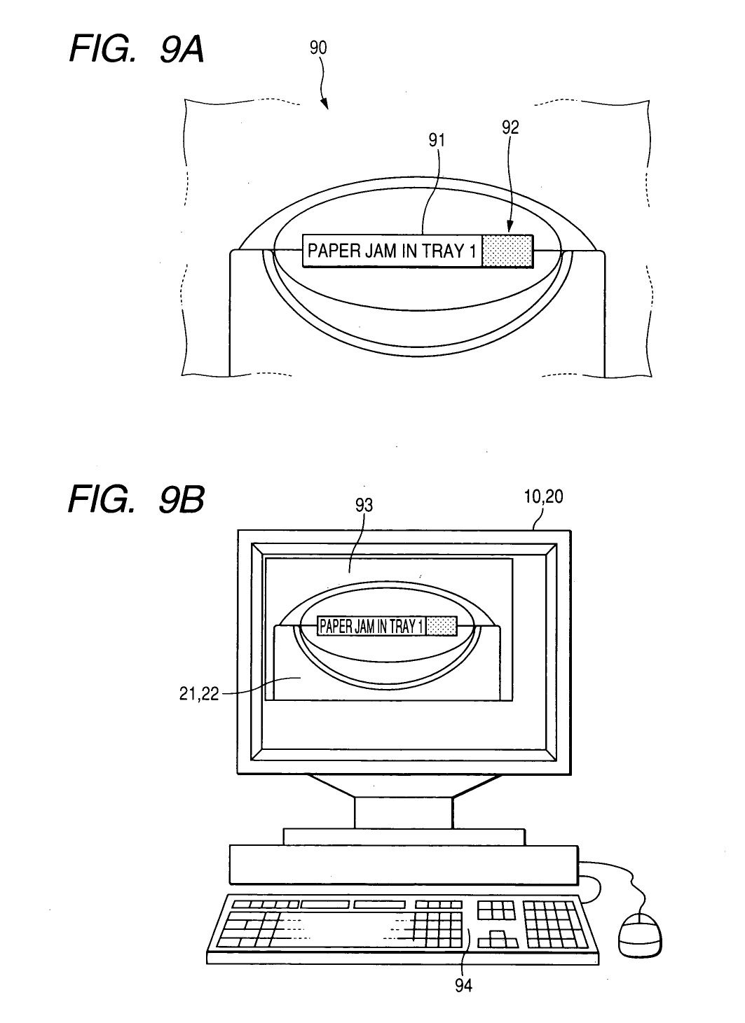

FIGS. 9A and 9B show a second embodiment. Difference of the second embodiment from the previous embodiment lies in that there is a difference in an error display of the printer 30 and a part of operations when the CPU 15, 25 serves as the pseudo pattern display unit and the designation unit. The remaining points are the same as those in first embodiment. Accordingly, parts the same as those in first embodiment are referenced correspondingly and duplicate description thereof will be omitted. Only the difference will be described next.

As shown in FIG. 9A, an operation panel 90 of a printer 30 is provided with a liquid crystal display portion 92 on which an error name 91 (error information) is displayed. On the other hand, a CPU 15, 25 displays a pseudo screen 93 of the liquid crystal display portion 92 on a display portion 21, 22. The user inputs the same characters as those of the error name 91 through an input unit 94 of a local computer 10 or a server computer 20 so as to display the characters. When the user then performs a predetermined determination operation, a piece of error handling information 81 corresponding to the error name is displayed on the screen. Incidentally, the error information is not limited to characters such as those of the error name 91 but may be symbols, figures, and the like.

Also in such a configuration, when the user merely uses the input unit 94 so that the error name 91 displayed on the liquid crystal display portion 92 of the printer 30 is displayed on the pseudo screen 93, the user can acquire a piece of error handling information 81 corresponding to the error name 91.

### Third Embodiment

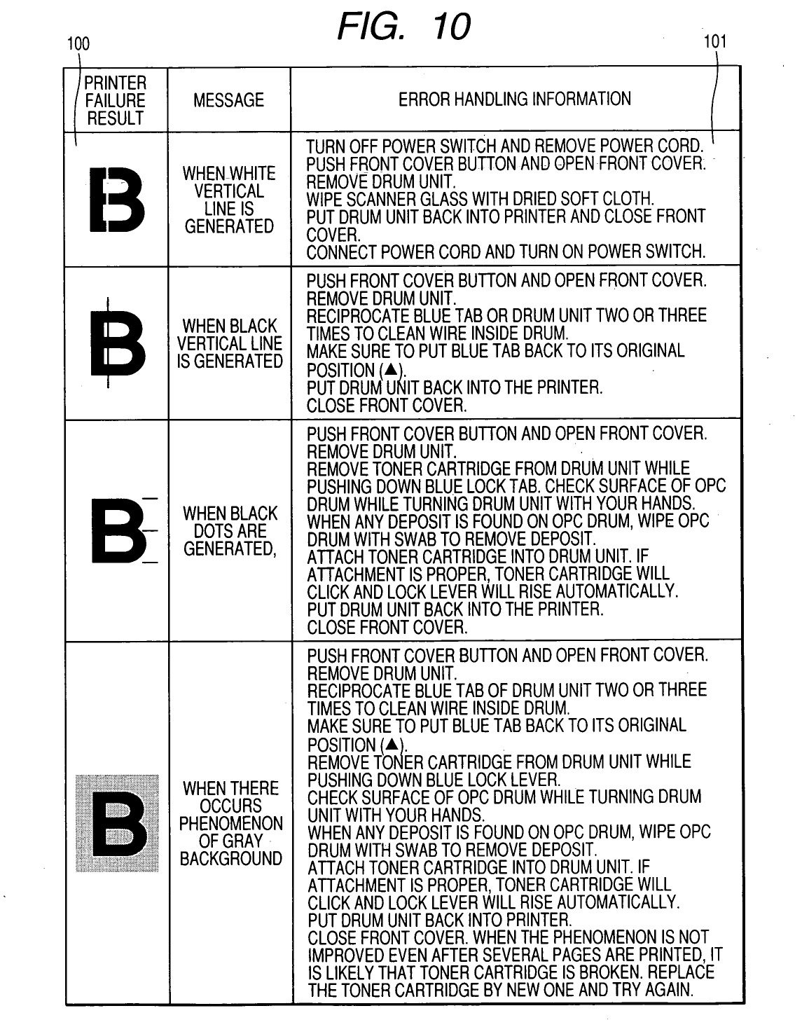

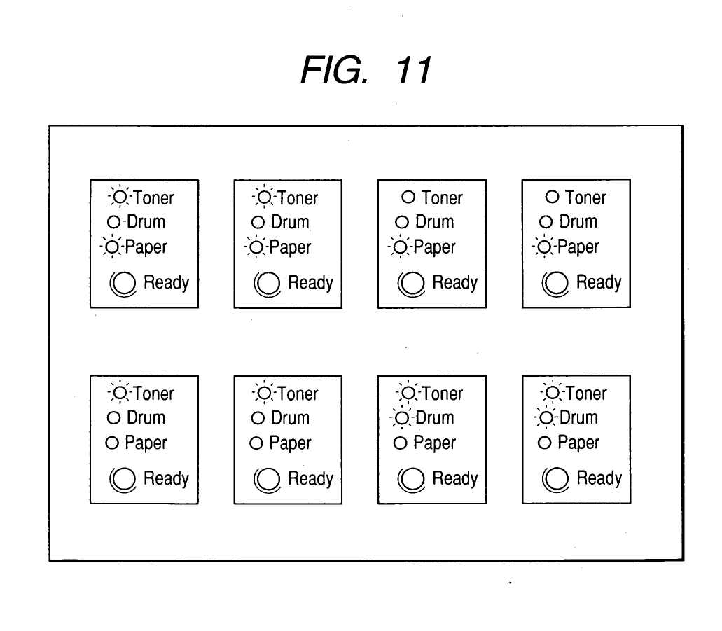

FIG. 10 shows a third embodiment. Difference of the third embodiment from the previous embodiment lies in the point that a piece of error handling information corresponding to a printing failure printed on paper by a printer 30 is displayed. The remaining points are the same as those in the first embodiment. Accordingly, parts the same as those in the first embodiment are referenced correspondingly and duplicate description thereof will be omitted. Only the difference will be described next.

Various printing failures (failures in image formation) such as a white vertical line, a black vertical line, and the like, may occur on the printed sheet of paper (i.e. the recording medium, which may be an OHP sheet etc. instead of paper) by the printer 30 as shown in the left column of FIG. 10. In the embodiment, pseudo patterns 100 corresponding to various printing failure patterns are displayed, for example, by a list on a display portion 12, 22. When a specific pseudo pattern is designated from these pseudo patterns 100, a piece of error handling information 101 (right column in FIG. 10) corresponding to the specific pseudo pattern is displayed on the screen.

According to the embodiment, when a pseudo pattern 100 corresponding to a printing failure pattern having occurred in the printer 30 is merely designated on the display screen of the display portion 12, 22, a piece of error handling information 101 corresponding to the pseudo pattern 100 can be acquired. Incidentally, the configuration of the third embodiment may be added to the configuration of the first or the second embodiments.

### Other Embodiments

The present invention is not limited to the embodiments described above with reference to the drawings. For example, the following embodiments are also included in the technical scope. In addition to the following description, various changes can be made without departing from the substance of the invention.

(1) In each of the aforementioned embodiments, the local computers 10 and the server computer 20 are connected to the printer 30 through the LAN (Local Area Network) so as to communicate with the printer 30. The invention is, however, not limited to this. For example, it is a matter of course that each computer 10, 20 may be a computer connected to the printer 30 locally through a parallel port, a USB port, or the like, or may be a computer not connected to the printer 30.

(2) The invention is not limited to the configuration where the error handling information 81 is displayed on the screen of the display portion 12, 22, but may be applied, for example, to the configuration where the error handling information 81 is printed and output by another printer connected to one of the local computers 10 or the server computer 20 so as to communicate therewith.

(3) Further, the first and the second embodiments have the configuration in which a specific emission pattern is reproduced on the pseudo panel screen 80. The invention is, however, not limited to this. For example, as shown in FIG. 10, a plurality of pseudo panels reflecting various emission patterns may be displayed by a list on the display portion 12, 22. In this case, it is preferable to use a configuration where pseudo panels high in rate of error incidence are displayed by priority. The display by a list is not limited to the configuration in which all the emission patterns are displayed together on the screen but may be applied to the configuration in which a screen scroll function is used to scroll the screen so that the emission patterns are displayed successively on the screen with a predetermined number of emission patterns being displayed at a time.

(4) In each of the aforementioned embodiments, the error handling information is regarded as character information. The invention is, however, not limited to this. The invention may be applied to the configuration where a corresponding page of the instruction manual is displayed on the screen, or the configuration where a handling procedure is displayed on the screen by animation or by slides.

(5) The error handling information display program may be configured so that a program dedicated to each printer is installed when a printer driver is installed, or may be configured to have general-purpose properties so as to selectively display a pseudo panel screen for the kind of a printer corresponding to the driver.

(6) The error handling information display program may be installed in advance only in the server computer 20. In this case, when each local computer 10 gains access to the server computer 20, a pseudo panel screen or the like is displayed on the display portion 12 of the local computer 10.

(7) The error handling information display program may be installed from a recording medium such as a CD or may be downloaded through the Internet.

(8) Although the printer 30 in the aforementioned first embodiment is provided with no liquid crystal display portion, the printer 30 may be provided with a liquid crystal display portion. However, there is a limitation in information that can be displayed on the liquid crystal display portion. It is therefore preferable to use the configuration to which the invention is applied.

(9) In the embodiments described above, the local computers 10 and server computer 20 are configured to serve as the “terminal apparatus” described in the embodiments. However, a mobile apparatus such as cellular phones and PDA devices in which the error handling information display program described above is installed may be provided to serve as the “terminal apparatus”. In this case, a user interface unit such as buttons or touch panels provided in the mobile apparatus serves as the “input unit” that is described in the embodiments, display provided in the mobile apparatus serves as the “display device” that is described in the embodiments, and RAMs (Random Access Memory) and/or memory cards provided in the mobile apparatus serves as the “storage unit” described in the embodiments. The mobile apparatus may be provided with a network interface to communicate with other devices and apparatuses.

(10) The error handling information 81 may be stored in the server computer 20. In this case, the local computer 10 is configured to download the error handling information 81 stored in the server computer 20 to a memory, and to use the error handling information 81 temporary stored in the memory. Alternatively, both of the local computer 10 and the server computer 20 may be configured to obtain the error handling information 81 from an external server such as a web server (http server) connected to the Internet.

According to the embodiments described above, when a pseudo pattern corresponding to a display pattern on the display portion of the image forming apparatus is merely designated on the display screen of the display device, a piece of error handling information corresponding to the pseudo pattern can be acquired.

According to the embodiments, the pseudo display portion corresponding to the display portion of the image forming apparatus is displayed on the screen and the pseudo patterns are displayed on the pseudo display portion. That is, a state near to an actual display pattern of the display portion of the image forming apparatus is reproduced on the display screen. Accordingly, it becomes easy for the user to designate a specific pseudo pattern visually.

According to the embodiments, even when correspondence between each emission pattern of the light emitting lamps (such as LEDs) and the contents of each error is not known, it is possible to acquire a piece of error handling information corresponding to the error easily.

According to the embodiments, it becomes easy to designate a specific pseudo pattern because a plurality of pseudo patterns are displayed by a list on the display screen of the display device. Incidentally, as for the display by a list, it is preferable to use a configuration in which only pseudo patterns high in frequency of use (high in rate of incidence of errors) are displayed by a list.

According to the embodiments, only when the user uses the input unit so that error information displayed on the display portion of the image forming apparatus are displayed on the display screen of the display device, the user can acquire apiece of error handling information corresponding to the error information.

According to the embodiments, when a pseudo pattern corresponding to an image formation failure pattern generated in the image forming apparatus is merely designated on the display screen of the display device, a piece of error handling information corresponding to the pseudo pattern can be acquired. Incidentally, the fourth or eleventh configuration may be designed to be provided additionally to any one of the first to third configurations or the eighth to tenth configurations.

The foregoing description of the embodiments has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application program to enable one skilled in the art to utilize the invention in various embodiments and with various modifications as are suited to the particular use contemplated. It is intended that the scope of the invention be defined by the claims appended hereto, and their equivalents.

What is claimed is:

1. A system comprising:
an apparatus having a display portion that displays a plurality of display patterns corresponding to a plurality of errors respectively; and
a terminal apparatus that has a display device that displays images of pieces of error handling information corresponding to the errors respectively,
wherein the terminal apparatus includes:
a pseudo pattern display unit that displays pseudo patterns corresponding to the display patterns respectively;
a designation unit that designates a specific pseudo pattern from among the pseudo patterns in accordance with an input signal from an input unit connected to the terminal apparatus; and
an error handling information output unit that reads one piece of error handling information corresponding to the specific pseudo pattern designated by the designation unit from among a plurality of pieces of error handling information, and outputs the read error handling information to be displayed.

2. The system according to claim 1, wherein the pseudo pattern display unit displays a pseudo display portion corresponding to the display portion of the apparatus, and displays the pseudo patterns on the pseudo display portion.

3. The system according to claim 1, wherein the display portion of the apparatus is provided with a light emitting lamp, and
wherein the pseudo patterns are patterns corresponding to emission patterns of the light emitting lamp, the emission pattern performed in accordance with the errors respectively.

4. The system according to claim 3, wherein the input unit allows a user to input the emission pattern of the light emitting lamp, and
wherein the designation unit designates a specific pseudo pattern from among the pseudo patterns in accordance with the emission pattern input through the input unit.

5. The system according to claim 1, wherein the pseudo pattern display unit displays the plurality of the pseudo patterns by a list.

6. The system according to claim 5, wherein the input unit allows a user to selectively input the pseudo pattern from among the list, and
wherein the designation unit designates a specific pseudo pattern from among the pseudo patterns in accordance with the pseudo pattern input through the input unit.

7. The system according to claim 6, wherein the pseudo pattern display unit displays a plurality of frequently-used ones of the plurality of the pseudo patterns by the list.

8. The system according to claim 1, wherein the display portion of the apparatus displays pieces of the error information including at least one of characters, signs and figures, and
wherein the plurality of the pseudo patterns are the pieces of error information corresponding to the errors respectively.

9. The system according to claim 8, wherein the pseudo pattern display unit displays the pieces of error information in accordance with an input signal input from the input unit, and
wherein the designation unit designates a corresponding piece of error information as the specific pseudo pattern when the error information is displayed.

10. A system comprising:
an image forming apparatus that forms an image on a recording medium; and
a terminal apparatus that has a display device that displays images of pieces of error handling information corresponding to various image formation failure patterns in the image forming apparatus respectively,
wherein the terminal apparatus includes:
a pseudo pattern display unit that displays pseudo patterns corresponding to the various image formation failure patterns respectively;
a designation unit that designates a specific pseudo pattern from among the pseudo patterns in accordance with an input signal from an input unit connected to the terminal apparatus; and
an error handling information output unit that reads one piece of error handling information corresponding to the specific pseudo pattern designated by the designation unit from among a plurality of pieces of error handling information stored in a storage unit, and outputs the read error handling information to be displayed.

11. The system according to claim 10, wherein the pseudo pattern display unit displays the plurality of the pseudo patterns by a list.

12. The system according to claim 11, wherein the input unit allows a user to selectively input the pseudo pattern from among the list, and
wherein the designation unit designates a specific pseudo pattern from among the pseudo patterns in accordance with the pseudo pattern input through the input unit.

13. The system according to claim 11, wherein the pseudo pattern display unit displays a plurality of frequently-used ones of the plurality of the pseudo patterns by the list.

14. A terminal apparatus comprising:
a display device that displays images of pieces of error handling information corresponding to a plurality of errors in an apparatus having a display portion that displays a plurality of display patterns corresponding to the plurality of the errors respectively;
a pseudo pattern display unit that displays pseudo patterns corresponding to the display patterns respectively;
a designation unit that designates a specific pseudo pattern from among the pseudo patterns in accordance with an input signal from an input unit connected to the terminal apparatus; and
an error handling information output unit that reads one piece of error handling information corresponding to the specific pseudo pattern designated by the designation unit from among a plurality of pieces of error handling information, and outputs the read error handling information to be displayed.

15. A terminal apparatus comprising:
a display device that displays images of pieces of error handling information corresponding to various image formation failure patterns in the image forming apparatus respectively;
a pseudo pattern display unit that displays pseudo patterns corresponding to the various image formation failure patterns respectively;
a designation unit that designates a specific pseudo pattern from among the pseudo patterns in accordance with an input signal from an input unit connected to the terminal apparatus; and
an error handling information output unit that reads one piece of error handling information corresponding to the specific pseudo pattern designated by the designation unit from among a plurality of pieces of error handling information stored in a storage unit, and outputs the read error handling information to be displayed.

16. A computer readable program product for causing a computer to display pieces of error handling information on a screen of a display device connected to the computer, the pieces of error handling information corresponding to a plurality of errors of an image forming apparatus having a display portion for displaying a plurality of display patterns corresponding to the plurality of errors respectively, the program product for causing the computer to execute procedures comprising:
displaying pseudo patterns corresponding to the display patterns respectively;
designating a specific pseudo pattern from among the pseudo patterns in accordance with an input signal input from an input unit connected to the computer;
reading one piece of error handling information corresponding to the designated specific pseudo pattern from among a plurality of pieces of error handling information; and
outputting the read error handling information to be displayed.

17. The computer readable program product according to claim 16, wherein in displaying the pseudo patterns, the pseudo patterns are displayed on a pseudo display portion corresponding to the display portion of the image forming apparatus.

18. The computer readable program product according to claim 16, wherein the pseudo patterns are patterns corresponding to emission patterns of a light emitting lamp provided on the display portion of the image forming apparatus, the emission pattern performed in accordance with the errors respectively.

19. The computer readable program product according to claim 18, further causing the computer to execute procedure of allowing a user to input the emission pattern of the light emitting lamp,
wherein the specific pseudo pattern is designated from among the pseudo patterns in accordance with the emission pattern input by the user.

20. The computer readable program product according to claim 16, wherein the plurality of the pseudo patterns are displayed by a list.

21. The computer readable program product according to claim 20, further causing the computer to execute procedure of allowing a user to selectively input the pseudo pattern from among the list,
wherein the specific pseudo pattern is designated from among the pseudo patterns in accordance with the pseudo pattern input by the user.

22. The computer readable program product according to claim 20, wherein a plurality of frequently-used ones of the plurality of the pseudo patterns are displayed by the list.

23. The computer readable program product according to claim 16, wherein the pieces of the error information is displayed on the display portion of the image forming apparatus as at least one of characters, signs and figures, and
wherein the plurality of the pseudo patterns are the pieces of error information corresponding to the errors respectively.

24. The computer readable program product according to claim 23, wherein the pieces of error information are displayed in accordance with an input signal input from the input unit, and
wherein a corresponding piece of error information is designated as the specific pseudo pattern when the error information is displayed.

25. A computer readable program product for causing a computer to display pieces of error handling information on a screen of a display device connected to the computer, the pieces of error handling information corresponding respectively to various image formation failure patterns in an image forming apparatus that forms an image on a recording medium, the program product for causing the computer to execute procedures comprising:
displaying pseudo patterns corresponding to the image formation failure patterns respectively;
designating a specific pseudo pattern from among the pseudo patterns in accordance with an input signal input from an input unit connected to the computer;
reading one piece of error handling information corresponding to the designated specific pseudo pattern from among a plurality of pieces of error handling information; and
outputting the read error handling information to be displayed.

26. The computer readable program product according to claim 25, wherein the plurality of the pseudo patterns are displayed by a list.

27. The computer readable program product according to claim 26, further causing the computer to execute procedure of allowing a user to selectively input the pseudo pattern from among the list,
wherein the specific pseudo pattern is designated from among the pseudo patterns in accordance with the pseudo pattern input by the user.

28. The computer readable program product according to claim 26, wherein a plurality of frequently-used ones of the plurality of the pseudo patterns are displayed by the list.

29. A system comprising:
an apparatus that visually outputs a plurality of error information; and
a terminal apparatus that visually outputs a plurality of pseudo error information corresponding to the error information,
wherein the terminal apparatus allows a user to designate a specific pseudo error information from among the plurality of pseudo pattern information, and outputs an error handling information corresponding to the specific pseudo error information designated by the user.

30. The system according to claim 29, wherein the terminal apparatus displays pseudo patterns on a pseudo display portion corresponding to a display portion of the apparatus, the display portion displaying a plurality of display patterns, and the pseudo patterns corresponding to the display patterns respectively.

31. The system according to claim 29, wherein the apparatus is provided with a light emitting lamp, and
wherein the terminal apparatus displays pseudo patterns corresponding to emission patterns of the light emitting lamp, the emission pattern performed in accordance with the error information respectively.

32. The system according to claim 31, wherein the terminal apparatus allows a user to input the emission pattern of the light emitting lamp, and
wherein the terminal apparatus designates a specific pseudo pattern from among the pseudo patterns in accordance with the emission pattern input by the user.

33. The system according to claim 29, wherein the terminal apparatus displays a plurality of pseudo patterns by a list, the pseudo patterns respectively corresponding to display patterns displayed by the apparatus.

34. The system according to claim 33, wherein the terminal apparatus allows a user to selectively input the pseudo pattern from among the list, and
wherein the terminal apparatus designates a specific pseudo pattern from among the pseudo patterns in accordance with the pseudo pattern input by the user.

35. The system according to claim 33, wherein the terminal apparatus displays a plurality of frequently-used ones of the plurality of the pseudo patterns by the list.

36. The system according to claim 29, wherein the apparatus displays pieces of the error information including at least one of characters, signs and figures.

37. The system according to claim 36, wherein the terminal apparatus displays the pieces of error information in accordance with an input by the user, and
wherein the terminal apparatus designates a corresponding piece of error information as a specific pseudo error information when the error information is displayed.
